(19) United States
(12) Patent Application Publication
(10) Pub. No.: US 2019/0141767 A1
(43) Pub. Date: May 9, 2019

(54) Interleaving Radio Access Technologies

(71) Applicant: Google LLC, Mountain View, CA (US)

(72) Inventors: Jibing Wang, Saratoga, CA (US); Erik Richard Stauffer, Sunnyvale, CA (US); Aamir Akram, San Jose, CA (US)

(73) Assignee: Google LLC, Mountain View, CA (US)

(21) Appl. No.: 15/939,060

(22) Filed: Mar. 28, 2018

Related U.S. Application Data
(60) Provisional application No. 62/583,468, filed on Nov. 8, 2017.

(51) Int. Cl. H04W 76/15; H04L 27/26; H04W 72/12; H03M 13/27

(52) U.S. Cl. CPC H04W 76/15; H04L 27/2656; H04W 16/14; H03M 13/2792; H04W 72/1215

(57) ABSTRACT

The present disclosure describes methods and apparatuses for interleaving radio access technologies. In some aspects, the systems include a user device with a first wireless connection of a first RAT and a second wireless connection of a second RAT. The user device receives a coordinated uplink schedule for transmitting via the first wireless connection and the second wireless connection. The user device transmits a first portion of data during a data frame via the first wireless connection. According to the coordinated uplink schedule, the transmission of the first portion of data is interrupted, by the user device, to transmit a signal via the second wireless connection of the second RAT. The user device may then resume transmitting the data frame by transmitting a second portion of the data frame via the first wireless connection.

### RELATED APPLICATION

This application claims priority under 35 U.S.C. § 119(e) to U.S. Provisional Patent Application 62/583,468, filed on Nov. 8, 2017, which is incorporated herein by reference in its entirety.

### BACKGROUND

Many user devices communicate over a wireless network provided by base stations, such as cell towers. Because of advances in wireless standards, user devices may be configurable to communicate, via the wireless network, using those standards. However, user devices capable of communicating via multiple wireless standards are generally configured with unique sets of hardware components associated with each of the standards. For example, a mobile phone may be configured with a unique set of hardware components to communicate via a 5^{th} generation (5G) new radio (NR) radio access technology (RAT). The mobile phone may also be configured with another unique set of hardware components to communicate via a 4^{th} generation (4G) Long Term Evolution (LTE) RAT.

However, many user devices have limited space. Eliminating hardware components can allow for a smaller device or an increased availability of space for improving another capability of the device, such as battery capacity. Additionally, each component of the device can increase manufacturing costs, decrease profit margins, or increase sales prices to consumers. Powering additional components also increases power consumption and decreases battery life. Thus, for a user device capable of communicating via multiple wireless standards, using multiple unique sets of hardware components causes a decreased amount of available space in the device, increased manufacturing costs, or increased power consumption.

### SUMMARY

This document describes techniques for, and systems that enable, interleaving radio access technologies (“RATs”) for communicating between a user device and one or more base stations of a wireless network. In some aspects, the systems include a user device with a first wireless connection of a first RAT and a second wireless connection of a second RAT. The user device receives a coordinated uplink schedule to allow the user device to interleave transmissions via the first wireless connection and the transmissions via the second wireless connection. This interleaving of transmissions allows the user device to use a single transmission chain or power amplifier for transmissions over the first RAT and the second RAT. The coordinated uplink schedule can interleave data frames, subframes, or slots of subframes to decrease transmission latency.

In some implementations, the user device transmits data during a data frame via the first wireless connection of the first RAT. Generally, a transmission chain of a user device transmit an entire data frame via a single wireless connection of a single RAT. However, using a coordinated uplink schedule, the user device can interrupt the transmission of the first portion of data to transmit a signal via the second wireless connection of the second RAT. This is referred to as “puncturing” the data frame to interleave radio access technologies. The user device may then resume transmitting the data during the data frame via the first wireless connection of the first RAT.

In some aspects, a user device punctures a data frame by providing a subframe, or a slot of a subframe, for transmission of a signal via a second wireless connection of a second RAT. In some implementations, the remaining subframes, or slots of subframes, are scheduled for transmitting via a first wireless connection of a first RAT. The signal may carry communication data or instructions for communication during a future data frame such as, for example, a following data frame scheduled for communicating via the second wireless connection of the second RAT. The communication data may include a sounding reference signal that is useful for improving a quality of the second wireless connection by the one or more base stations of the wireless network.

In some aspects, a user device punctures a data frame by interrupting, within a subframe or slot of a subframe, a transmission of data via a first wireless connection of a first RAT. In these implementations, the user device begins transmission of data during a subframe of a data frame. The user device transmits the data via the first wireless connection of the first RAT. The user device then halts the transmission of the data based on a determination to transmit a signal via a second wireless connection of a second RAT. The user device may determine to transmit the signal via the second wireless connection based on a priority of the signal being higher than a priority of the data. A transmitter of the user device then transmits the signal, during the subframe, via the second wireless connection of the second RAT. Upon completion of the transmission of the signal, the user device may resume transmission of the data via the first wireless connection. The user device may use a single transmission chain or power amplifier to transmit the data and the signal.

These techniques and systems may be implemented, for instance, in wireless networks that implement two or more wireless connections using wide-band (e.g., 20 MHz to 1 GHz) communication protocols, such as a 4^{th} generation (4G) Long Term Evolution (LTE) protocol, an LTE advanced protocol, or a 5^{th} generation (5G) new radio (NR) protocol. These techniques and systems may be particularly beneficial when the user device is connected to a wireless network including an advanced protocol, such as the 5G NR RAT and a less-advanced, or lower-frequency, protocol, such as the LTE RAT. The 5G NR wireless connection may be configured to primarily provide a large downlink bandwidth and a small uplink bandwidth and the LTE wireless connection may be configured to provide a relatively large uplink bandwidth. The techniques may be used to reduce an amount of bandwidth that is needed for transmission of 5G NR signals by allowing transmission of the 5G NR signals during a portion of a data frame or subframe that is scheduled for uplink via the LTE wireless connection.

The details of one or more implementations are set forth in the accompanying drawings and the following description. Other features and advantages will be apparent from the description and drawings, and from the claims. This summary is provided to introduce subject matter that is further described in the Detailed Description and Drawings. Accordingly, this summary should not be considered to describe essential features nor used to limit the scope of the claimed subject matter.

### BRIEF DESCRIPTION OF THE DRAWINGS

The details of one or more aspects of interleaving radio access technologies for wireless networks is described below. The use of the same reference numbers in different instances in the description and the figures may indicate like elements.

FIG. 1 illustrates example device configurations of a user device and a base station in accordance with one or more aspects of interleaving radio access technologies.

FIG. 2 illustrates an example networking environment in which the user device and base station may communicate in accordance with one or more aspects of interleaving radio access technologies.

FIG. 3 illustrates a series of data frames and subframes in accordance with one or more aspects of interleaving radio access technologies.

FIG. 4 illustrates a data frame having a punctured subframe in accordance with one or more aspects of interleaving radio access technologies.

FIG. 5 illustrates a data frame of a first wireless connection of a first RAT and a second wireless connection of a second RAT that are scheduled such that a user device transmits via only one of the first wireless connection or the second wireless connection at a time.

FIG. 6 illustrates a series of data frames having a subframe for providing a frame RAT indicator to indicate a RAT of a future data frame or subframe.

FIG. 7 illustrates an example user interface of a user device through which one or more aspects of interleaving radio access technologies can be implemented.

FIG. 8 illustrates an example method for interleaving radio access technologies.

FIG. 9 illustrates another example method for interleaving radio access technologies.

FIG. 10 illustrates another example method for interleaving radio access technologies.

FIG. 11 illustrates another example method for interleaving radio access technologies.

### DETAILED DESCRIPTION

Generally, a user device communicates through a wireless connection of a radio access technology via a unique power amplifier and transmission chain. The user device may also be configured to communicate with another wireless connection of another radio access technology via another unique power amplifier and transmission chain. However, operation of two unique power amplifier and transmission chains requires increased power consumption and manufacturing cost while sacrificing valuable space within the device. Additionally, communicating through both wireless connections via a single power amplifier and transmission chain can lead to a decrease in available bandwidth for application data (e.g., video streaming, web browsing, or gaming) based on inefficient use of data frames as the power amplifier and transmission chain toggles between frames of each wireless connection.

This document describes techniques and systems for interleaving radio access technologies (“RATs”) to allow improved management of wireless connections using two or more RATs. These techniques and systems can improve usage of physical space in a user device, reduce manufacturing costs, and improve a user experience by increasing available bandwidth for application data. These techniques include allowing a data frame to include transmissions of a first wireless connection of a first RAT and a second wireless connection of a second RAT.

In some aspects of interleaving RATs, a user device establishes a first wireless connection of a first RAT and a second wireless connection of a second RAT. The user device receives a coordinated uplink schedule for transmitting via the first wireless connection and the second wireless connection. The coordinated uplink schedule may be received from a base station operating one or both of the first wireless connection or the second wireless connection. Further, the coordinated uplink schedule can avoid simultaneous transmissions by the user device via the first wireless connection and the second wireless connection. The user device begins communicating during a data frame via the first wireless connection. Based on the coordinated uplink schedule, the user device halts the communication via the first wireless connection and transmits a signal via the second wireless connection. For example, the user device may puncture the data frame by utilizing a subframe or a slot of a subframe to transmit the signal via the second wireless connection. Alternatively, the user device may puncture a subframe of the data frame by transmitting the signal via the second wireless connection during a portion of the punctured subframe. The punctured subframe may be utilized to transmit data via the first wireless connection before, after, or before and after the transmission of the signal via the second wireless connections.

By allowing the second wireless connection of the second RAT to puncture the data frame to transmit the signal, the user device can use a single transmission chain to transmit via the first wireless connection and the second wireless connection. Allowing the second wireless connection of the second RAT to puncture the data frame to transmit the signal also allows the user device to transmit the signal using less than a full data frame, thereby decreasing latency for transmitting the signal and allowing for more efficient use of the data frame when the signal does not require a full bandwidth provided by the data frame.

The following discussion describes an operating environment, an example networking environment in which devices of the operating environment may be implemented, and techniques that may be employed in the operating environment or the network environment. In the context of the present disclosure, reference is made to the operating environment or networking environment by way of example only.

Operating Environment

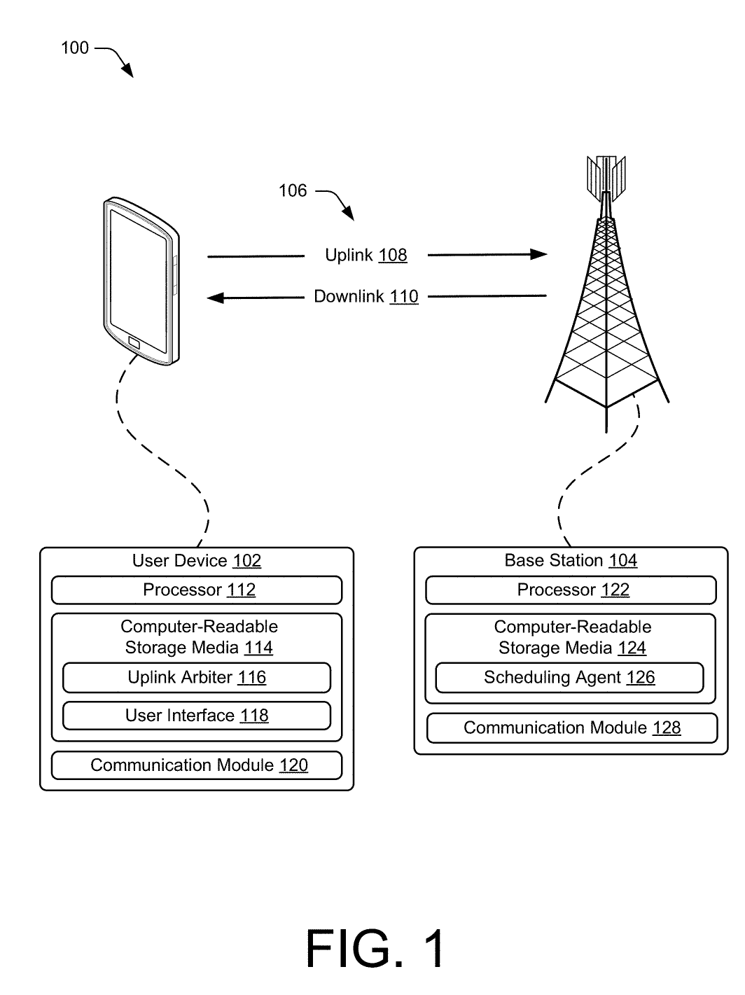

FIG. 1 illustrates an example operating environment 100 in which devices for interleaving radio access technologies can be implemented. In this example, the operating environment includes a user device 102 and a base station 104 that are respectively configured to communicate over a wireless link 106 of a wireless network. Generally, the wireless link 106 includes an uplink 108 by which the user device 102 transmits data or information to the base station 104 and a downlink 110 by which the base station 104 transmits other data or other information to the user device 102. The wireless link 106 may be implemented having one or more wireless connections in accordance with any suitable protocol or standard, such as a Global System for Mobile Communications (GSM), Worldwide Interoperability for Microwave Access (WiMax), a High Speed Packet Access (HSPA), Evolved HSPA (HSPA+) protocol, an LTE protocol (e.g., 4G), an LTE Advanced protocol, or a 5G NR protocol. Although shown or described with reference to a separate uplink 108 or downlink 110, communication between the user device 102 and base station 104 may also be referred to as a wireless connection, wireless association, frame exchange, or communication link.

The user device 102 includes a processor 112, computer-readable storage media (CRM) 114 having an uplink arbiter 116 and a user interface 118, and a communication module 120. The user device 102 is illustrated as a smart phone, however the user device 102 may instead be implemented as any device with wireless communication capabilities, such as a mobile gaming console, a tablet, a laptop, an advanced driver assistance system (ADAS), a point-of-sale (POS) terminal, a health monitoring device, a drone, a camera, a media-streaming dongle, a wearable smart-device, an internet-of-things (IoT) device, a personal media device, a navigation device, a mobile-internet device (MID), a wireless hotspot, a femtocell, or a broadband router.

The processor 112 of the user device 102 can execute processor-executable instructions or code stored by the CRM 114 to cause the user device to perform operations or implement various device functionalities. In some cases, the processor 112 is implemented as an application processor (e.g., multicore processor) or a system-on-chip with other components of the user device integrated therein. The CRM 114 may include any suitable type of memory media or storage media, such as read-only memory (ROM), programmable ROM (PROM), random access memory (RAM), static RAM (SRAM), or Flash memory. In the context of this discussion, the CRM 114 of the user device 102 is implemented as hardware-based storage media, which does not include transitory signals or carrier waves. In some cases, the CRM 114 stores firmware, an operating system, or applications of the user device 102 as instructions, code, or information. The instructions or code can be executed by the processor 112 to implement various functionalities of the user device 102, such as those related to network access or audio encoding features. In this example, the CRM 114 also stores processor-executable code or instructions for implementing the uplink arbiter 116 and the user interface 118 of the user device 102.

The communication module 120 of the user device 102 includes a hardware-based transceiver. The hardware-based transceiver includes a receiver, a transmitter, and associated circuitry or other components for communicating with the base station 104 via a wireless medium. For example, the communication module 120 may transmit, via the transmitter, data or information to the base station 104 via the uplink 108. This data or information transmitted to the base station 104 may include any suitable type of framed or packetized information, such as one or more of device status information, wireless link status information, wireless link control information, data requests, data, or network access requests. The communication module 120 may also receive, via the receiver, communication data from the base station 104, such as wireless link configuration settings, network control information, or communication mode selection. For example, the communication module 120 may receive a coordinated uplink schedule, which includes interleaved uplink grants for the first wireless connection and the second wireless connection. The communication module 120 receives the coordinated uplink schedule from the base station 104, which allows the communication module 120 to transmit via the first wireless connection during a first portion of a data frame and via the second wireless connection during a second portion of the data frame. For example, one or both of the first portion of the data frame and the second portion of the data frame may include one or more sets of subframes or slots of subframes, respectively. A first set of subframes or slots of subframes of the first portion may be distinct from a second set of subframes or slots of subframes of the second portion. Alternatively, the first set of subframes or slots of subframes can overlap using a puncturing technique.

In some aspects, the uplink arbiter 116 may determine a priority of data and signals to be transmitted by the user device 102. For example, communication data, such as a sounding reference signal (SRS), may be given a relatively high priority and background application data may be given a relatively low priority. Additionally, transmission data for transmitting via a wireless connection of a RAT may be given a priority that is higher than transmission data for transmitting via another wireless connection of another RAT. The uplink arbiter 116 may cause a transmission of high-priority data to interrupt, or puncture, a transmission of a data frame of low-priority data. This interruption, or puncturing, may be coordinated between the base station 104, which provides the wireless connection, and another base station, which provides the other wireless connection. For example, the uplink arbiter 116 may determine that it would be beneficial to transmit high-priority transmission data of a first RAT during a data frame that would otherwise be scheduled for transmissions of a second RAT. The user device 102 communicates the determination to the base station 104, which may provide a coordinated uplink schedule that schedules a portion of the data frame for transmission of the high-priority transmission data.

Additional communication data may include, for example, device status information, wireless link status information, wireless link control information, data requests, communication instructions, or network access requests. More specifically, the communication data may include one or more of acknowledge/not acknowledge (ACK/NACK) data, channel quality indicator (CQI) data, an access probe, a channel request, or channel state information (CSI) data for one or both of the wireless connections. Additionally or alternatively, the communication data may include, or be carried on, one or more of a random access channel (RACH) communication, a radio resource control (RRC) communication, or a non-access stratum communication. Further, the communication data may be transmitted as a unique communication, a portion of a preamble, or medium access control (MAC) layer of a communication packet. The communication data may be transmitted via various communication channels of the uplink 108, such as a physical uplink control channel (PUCCH) or a physical uplink share channel (PUSCH).

The user interface 118 may provide a notification of interleaving transmissions of different RATs. Additionally or alternatively, the user interface 118 may provide a menu for receiving a selection to enter a multi-carrier mode in which the phone establishes a first wireless connection of a first RAT and a second wireless connection of a second RAT and interleaves at least transmissions of the wireless connections. These are but a few implementations of the uplink arbiter 116 and the user interface 118, which are described further or with other aspects throughout the disclosure.

In this example, the base station 104 is shown generally as a cellular base station of a wireless network. The base station 104 may be representative of a single cellular base station having multiple transmitters capable of establishing multiple wireless connections and transmitting via multiple RATs. Alternatively, the base station 104 may represent a system of multiple cellular base stations that are collectively capable of establishing multiple wireless connections and transmitting via multiple RATs. The base station 104 may be implemented to manage a cell of a wireless network that includes multiple other base stations that each manage another respective cell of the wireless network. As such, the base station 104 may communicate with a network management entity or others of the multiple base stations to coordinate connectivity or hand-offs of mobile stations within or across the cells of the wireless network. The base station 104 can be configured as any suitable type of base station or network management node, such as a GSM base station, a node base (Node B) transceiver station (e.g., for UMTS), an evolved NodeB (eNB, e.g., for LTE), or a next generation Node B (gNB, e.g., for 5G NR). As such, the base station 104 may control or configure parameters of the uplink 108 or the downlink 110 in accordance with one or more of the wireless standards or protocols described herein.

The base station 104 includes a processor 122, a computer-readable storage media (CRM) 124 having a scheduling agent 126, and a communication module 128. The processor 122 can execute processor-executable instructions or code stored by the CRM 124 to perform operations or implement various base station functionalities. In some cases, the processor 122 is implemented as multiple processor cores or a multicore processor configured to execute firmware or an operating system of the base station 104. The CRM 124 may include any suitable type of memory media or storage media, such as ROM, PROM, RAM, SRAM, or Flash memory. In the context of this discussion, the CRM 124 is implemented as hardware-based storage media, which does not include transitory signals or carrier waves. The CRM 124 of the base station 104 may store firmware, an operating system, or applications of the base station as instructions, code, or other information. The instructions or code can be executed by the processor 122 to implement various functionalities of the base station 104, such as to manage connectivity or parameters of the wireless link 106 with the user device 102. In this example, the CRM 124 also stores processor-executable code or instructions for implementing the scheduling agent 126 of the base station 104.

The communication module 128 of the base station 104 includes a hardware-based transceiver. The hardware-based transceiver includes a receiver, a transmitter, and associated circuitry or other components for communicating with the user device 102 via the wireless medium. In some cases, the communication module 128 includes, or is coupled with, multiple transceivers and antenna arrays that are configured to establish and manage wireless links with multiple user devices or mobile stations. The base station 104 may communicate any suitable data or information to the user device 102 (or other mobile stations) through the downlink 110, such as a schedule of one or more data frames, uplink grants, application data, wireless link status information, or wireless link control information.

In some aspects, the scheduling agent 126 of the base station 104 is implemented to perform various functions associated with interleaving RATs for communication between a user device and one or more base stations of a wireless network. The scheduling agent 126 performs various functions associated with allocating physical access or communication resources available to the base station 104. The physical access, such as an air interface of the base station 104, may be partitioned or divided into various units (e.g., frames) of bandwidth, time, carriers, or symbols. For example, within a framework of the LTE protocol, the scheduling agent 126 can allocate bandwidth and time intervals for transmission and receipt of data using the uplink 108 and the downlink 110 of the wireless link 106 via uplink grants and downlink grants, respectively. In some implementations, the communication module 128 may transmit coordinated uplink schedules to the user device 102 to cause the user device 102 to transmit via the first wireless connection during a first set of subframes or slots of subframes and to transmit via the second wireless connection during a second set of subframes or slots of subframes. The first set of subframes or slots of subframes may be distinct from the second set of subframes or slots of subframes. Alternatively, the first set of subframes or slots of subframes can overlap using a puncturing technique.

In some implementations, the scheduling agent 126 schedules transmissions via the downlink 110 of the first wireless connection and the second wireless connection such that the base station 104 transmits, to the user device 102, via only one wireless connection at a time such that the user device 102 receives transmissions from only one wireless connection at a time. In this way, the user device 102 may operate using only one receiver while communicating via both of the first wireless connection of the first RAT and the second wireless connection of the second RAT.

Furthermore, the base station 104 may communicate with the user device via a common physical downlink control channel (PDCCH). In some implementations, the PDCCH can carry an indication of a RAT of a future data frame. For example, during a data frame of a first wireless connection of a first RAT, a PDCCH includes an indication that a following data frame is of a second wireless connection of a second RAT. Additionally or alternatively, a physical hybrid automatic repeat requests (HARQ) indicator channel (PHICH) of one of the first wireless connection or the second wireless connection is used to transmit, to the user device 102, acknowledge/not acknowledge data for the other of the first wireless connection or the second wireless connection.

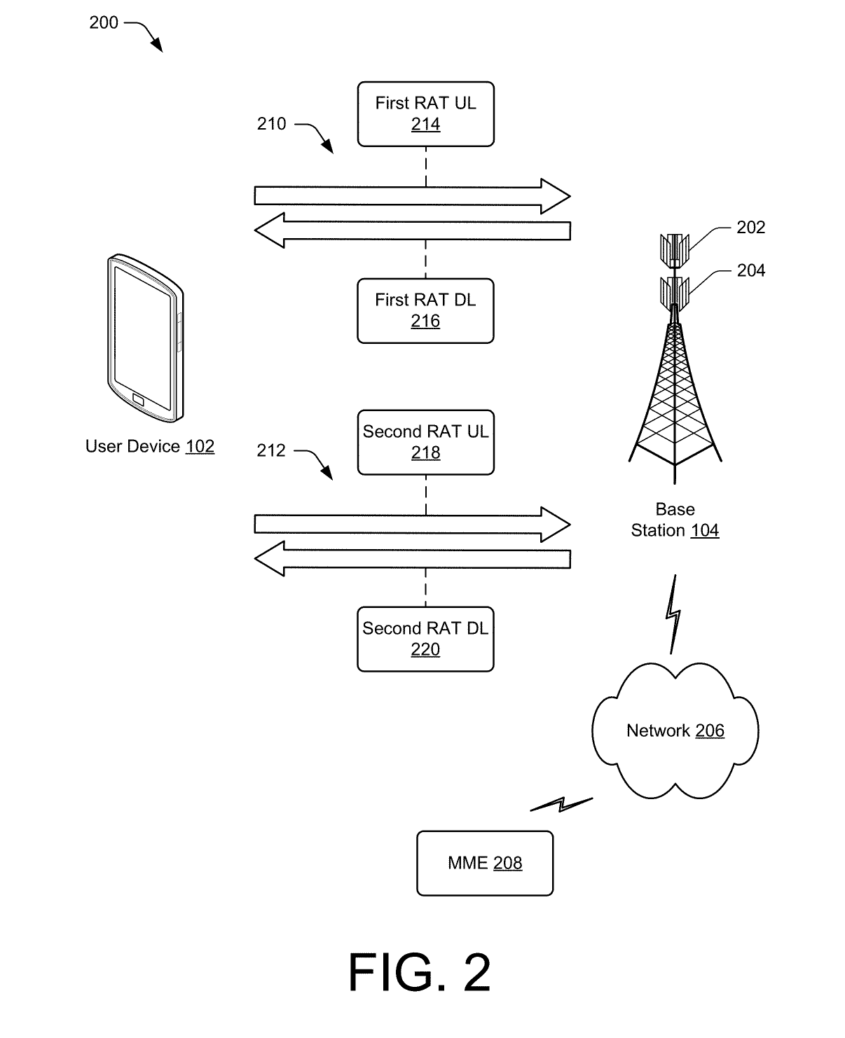

FIG. 2 illustrates an example networking environment 200 in which a user device and a base station may communicate over a wireless network in accordance with one or more aspects of interleaving radio access technologies. The network environment includes respective instances of the user device 102 and the base station 104, which includes a first transceiver 202 and a second transceiver 204. Through the wireless network, the base station 104 may provide access to other networks or resources, such as a network 206 (e.g., the Internet) connected via a backhaul link (e.g., fiber network). Additionally or alternatively, the networking environment 200 may include additional base stations or a mobility management entity (MME) 208 to manage the base stations of the wireless network and provide an area wide wireless network, such as a multi-component carrier network, and associated data services. For example, the MME 208 may manage the base station 104 such that the base station 104 provides a first wireless connection 210 and a second wireless connection 212 for communicating with the user device 102.

The first wireless connection 210 is provided by the first transceiver 202 and the second wireless connection 212 is provided by the second transceiver 204. The first wireless connection 210 includes a first RAT uplink (UL) 214 and a first RAT downlink (DL) 216. The second wireless connection 212 includes a second RAT uplink 218 and a second RAT downlink 220. In an example implementation, the first wireless connection 210 uses a 4G LTE RAT and the second wireless connection 212 uses a 5G NR RAT. In another example implementation, the first wireless connection 210 of the wireless link uses a 5G NR RAT and the second wireless connection 212 uses a 4G LTE RAT. In other implementations, the first wireless connection 210 uses any wireless protocol or standard and the second wireless connection 212 uses any other wireless protocol or standard.

In the context of interleaving RATs, the base station 104 transmits a coordinated uplink schedule to the user device 102 to coordinate the first RAT uplink 214 and the second RAT uplink 218. The user device 102 transmits, via the first RAT uplink 214, data during data frames, subframes, or slots scheduled for use by the first wireless connection 210. The user device 102 transmits, via the second RAT uplink 218, data during data frames, subframes, or slots scheduled for use by the second wireless connection 212. The base station 104 may further schedule puncturing of a slot that would otherwise be scheduled for transmitting by the first wireless connection 210 for transmission of a signal via the second wireless connection 212. Similarly, the user device 102 may allow puncturing of a slot that would otherwise be used by the second wireless connection 212 for transmission of a signal via the first wireless connection 210. As discussed above, puncturing may include allowing transmission of a signal of the second wireless connection 212 during a portion of a data frame, subframe, or slot that would otherwise be scheduled for transmission via the first wireless connection 210.

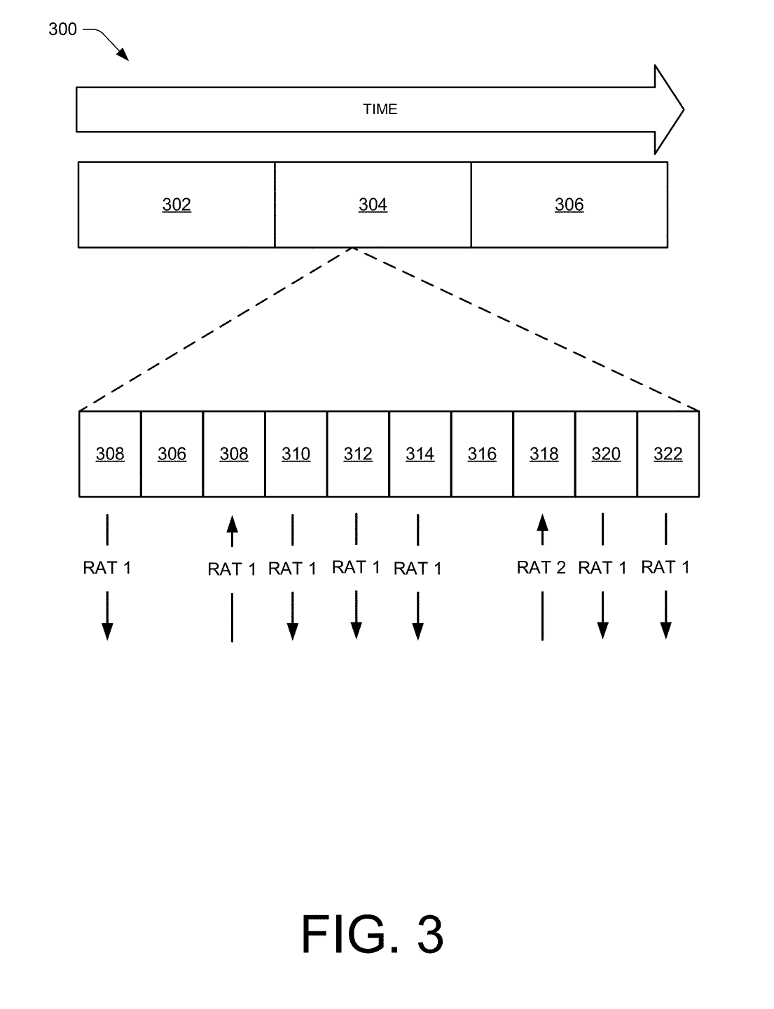

FIG. 3 illustrates a series 300 of data frames and subframes in accordance with one or more aspects of interleaving radio access technologies. Data frames 302, 304, and 306 include communication resources of the wireless link 106 over a period of time (e.g., 10 ms). The data frame 304 is shown in detail having subframes 308, 310, 308, 310, 312, 314, 316, 318, 320, and 322. The subframes 308, 310, 312, 314, 320, and 322 are scheduled for receiving via the first RAT downlink 216. The subframe 308 is scheduled for transmitting via the first RAT uplink 214. The data frame 304 is punctured by including the subframe 318 that is scheduled for transmitting a signal via the second RAT uplink 218. Because the data frame 304 includes time intervals for communicating via both of the first wireless connection 210 and the second wireless connection 212, the data frame 304 includes interleaved RATs.

The scheduling of the subframe 318 may be based on a coordinated uplink schedule received from a base station, such as the base station 104. The user device 102 may semi-statically or dynamically request an interleaved uplink schedule from the base station 104 (e.g., based on an expected need to transmit a signal via the second RAT uplink 218). The user device may transmit the request for an interleaved uplink schedule based on a determination by the uplink arbiter 116 that a priority of data, or a signal, to be transmitted via the second RAT uplink 218 is higher than a priority of data that would otherwise be transmitted via the first RAT uplink 214. The data that would otherwise be transmitted via the first RAT uplink 214 may include application data or other data that can be delayed without significant disruption of the first wireless connection 210.

A semi-static request for an interleaved uplink schedule may be based on a predicted need for a recurring transmission predicted by the user device 102. For example, the user device 102 may predict that a signal, such as an SRS, for the second RAT uplink 218 should be transmitted during a data frame preceding a data frame scheduled for communication via one or both of the second RAT uplink 218 or the second RAT downlink 220. In such an example, the data frame 306 is scheduled for communication via one or more of the second RAT uplink 218 and the second RAT downlink 220. Because the data frame 304 precedes the data frame 306, the user device 102 predicts that an SRS should be transmitted during the data frame 304 to improve a signal quality, through beam forming, for the communication scheduled for the data frame 306. Therefore, the user device 102 semi-statically schedules the subframe 318 for transmission via the second RAT uplink 218.

A dynamic request for an interleaved uplink schedule may be based on unpredicted conditions such as a change in a status of the user device 102 or generation of irregular data for transmission. For example, the user device 102 may move to a handoff location where the second wireless connection 212 of the user device 102 is handed off from one base station to another. In some implementations, the user device 102 may change status based on, for example, a charge of a battery of the user device 102, a decreased signal quality of the second wireless connection 212, or a user selected status. In such an example, the user device 102 determines that transmission of a signal indicating the change in status should be transmitted before a next data frame or subframe scheduled for the second RAT uplink 218.

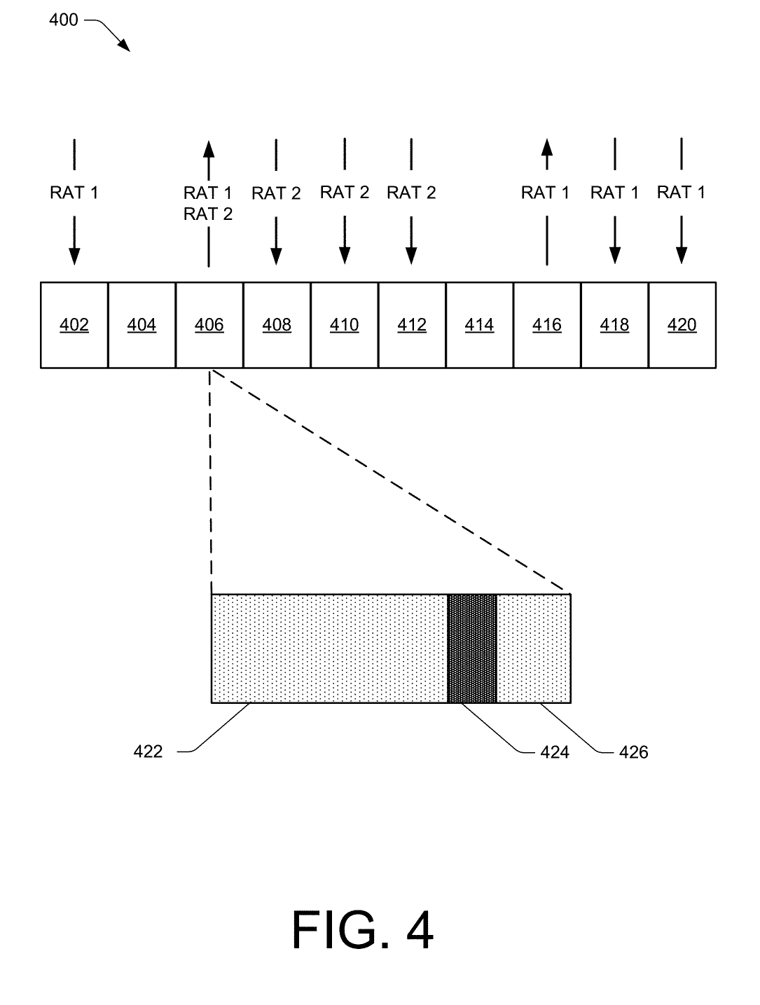

FIG. 4 illustrates a data frame 400 having a punctured subframe in accordance with one or more aspects of interleaving radio access technologies. The data frame 400 includes subframes 402, 404, 406, 408, 410, 412, 414, 416, 418, and 420 for communication via the first wireless connection 210 and the second wireless connection 212. The subframes 402, 418, and 420 are scheduled for the first RAT downlink 216; the subframes 408, 410, and 412 are scheduled for the second RAT downlink 220; the subframe 416 is scheduled for the first RAT uplink 214; and the subframe 406 is scheduled for the first RAT uplink 214 and the second RAT uplink 218. Because the data frame 400 includes time intervals for communicating via both of the first wireless connection 210 and the second wireless connection 212, the data frame 400 includes interleaved RATs.

The subframe 406 has a first portion 422 of bandwidth for transmitting via the first RAT uplink 214, a second portion 424 of bandwidth for transmitting via the second RAT uplink 218, and a third portion 426 of bandwidth for transmitting via the first RAT uplink 214. The portion 424 of the bandwidth may be at a beginning or end of the subframe, and thus, the portions 422 and 426 of the bandwidth may be adjacent or combined. In some implementations, the second portion 424 of bandwidth is sized based on a signal to be transmitted. For example, if the signal to be transmitted via the second RAT uplink 218 is an SRS, the bandwidth may be small (e.g., extending for only 60-100 microseconds).

In some implementations, the second wireless connection 212 includes a scheduled transmission after the subframe 406 and after the subframe 410. The user device 102 or the base station 104 may determine that it would be beneficial to puncture the subframe 406 to transmit a signal during the portion 424 based a scheduled reception of data via the second wireless connection 212 during the subframe 408 being before a next scheduled transmission via the second wireless connection 212. In these implementations, the scheduled reception (e.g., subframe 408) is scheduled between the transmission of the signal of the second RAT and a next scheduled transmission via the second wireless connection 212.

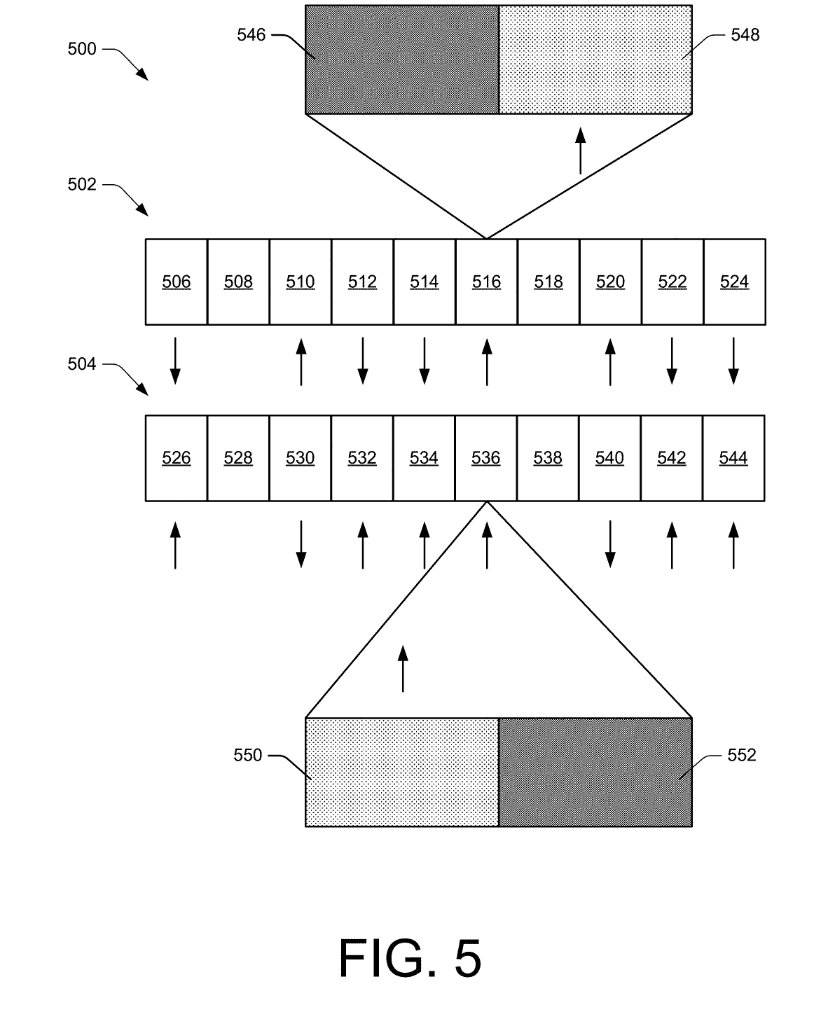

FIG. 5 illustrates a pair 500 of contemporaneous data frames including a data frame 502 of a first wireless connection of a first RAT and a data frame 504 of a second wireless connection of a second RAT. The pair 500 of contemporaneous data frames are scheduled via a coordinated uplink schedule such that a user device transmits via only one of the first wireless connection or the second wireless connection at a time. In some implementations, the first wireless connection and the second wireless connection use co-banded frequency ranges to facilitate transmitting and receiving via a single transceiver. The data frame 502 includes subframes 506, 508, 510, 512, 514, 516, 518, 520, 522, and 524, with the subframes 510, 516, and 520 scheduled for the first RAT uplink 214. The data frame 504 includes subframes 526, 528, 530, 532, 534, 536, 538, 540, 542, and 544, with the subframes 526, 532, 534, 536, 542, and 544 scheduled for transmitting via the second RAT uplink 218.

The subframe 516 is shown having a first slot 546 and a second slot 548. The second slot of the subframe 516 is scheduled for transmitting via the first RAT uplink 214. Each of the other subframes of the first data frame 502 and the second data frame 504 may also include multiple slots for transmitting, receiving, or neither. For example, the subframe 536 includes a first slot 550 and a second slot 552, where the first slot 550 is scheduled for transmitting via the second RAT uplink 218. In this way, the contemporaneous subframes 516 and 536 are both used for transmitting and receiving without transmitting via different RATs at a same time.

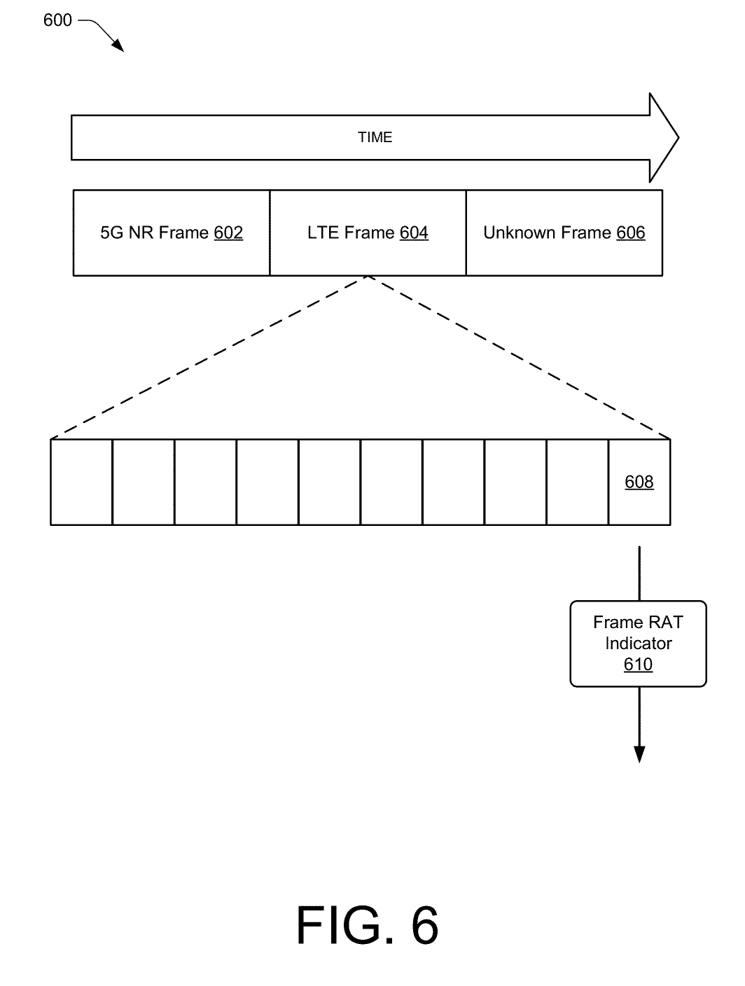

FIG. 6 illustrates a series 600 of data frames having a subframe for providing a frame RAT indicator to indicate a RAT of a future data frame or subframe. The series 600 of data frames includes a 5G NR frame 602, an LTE frame 604, and an unknown frame 606. The LTE frame 604 includes a subframe 608 that is scheduled for a downlink (e.g., the first RAT downlink 216). The subframe 608 includes a frame RAT indicator 610 that indicates, to the user device 102, whether the unknown frame 606 will be a 5G NR frame or an LTE frame. In some implementations, the subframe 608 is a last subframe of the LTE frame 604. In other implementations, the subframe 608 is a last subframe of the subframe 604 that is scheduled for a downlink.

The frame RAT indicator 610 may be transmitted by the base station 104 and received by the user device 102 via a PDCCH during the subframe 608. More particularly, the frame RAT indicator 610 may be included in a downlink control information (DCI) message carried on the PDCCH. Furthermore, the PDCCH may operate as a common PDCCH for communication of DCI messages for the first wireless connection 210 and the second wireless connection 212.

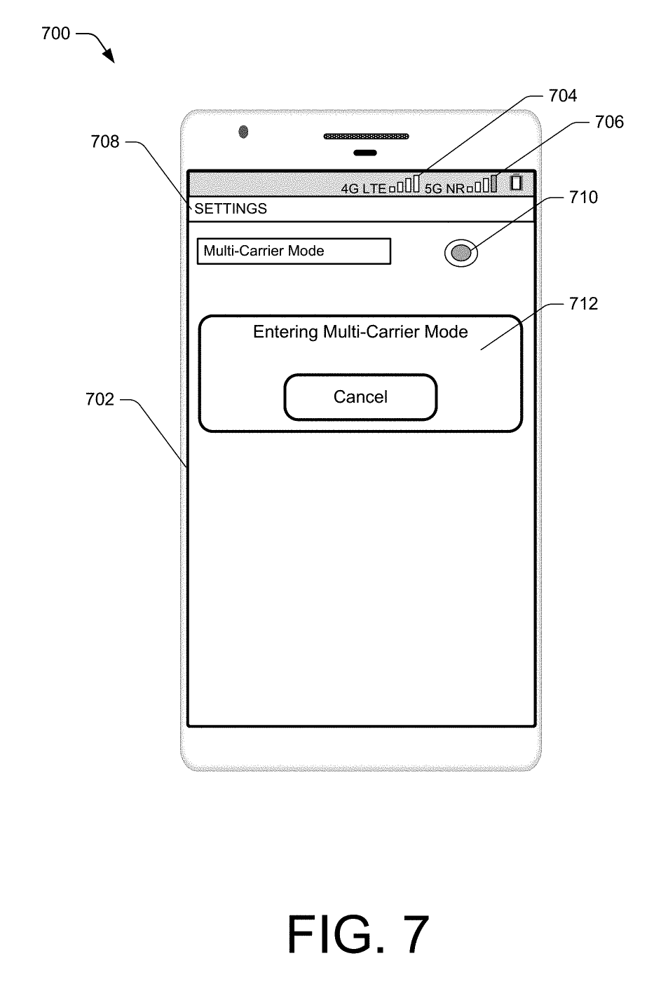

FIG. 7 illustrates an example user interface 700 of a user device through which one or more aspects of interleaving radio access technologies can be implemented. In this example, the user interface 700 is presented through a visible portion of a display 702 for providing output to a user. The display 702 may also include, or be integrated with, a touch screen or touch-sensitive overlay for receiving touch input from the user. The display 702 may also display a signal-quality indicator 704 of a first wireless connection of a first RAT (shown as 4G LTE) and a signal-quality indicator 706 of a second wireless connection of a second RAT (shown as 5G NR). In some cases, the display 702 provides, or makes accessible, a settings menu 708 through which the user interface 700 can receive input 710 to select a multi-carrier mode for communication. The input 710 can be effective to cause the user device 102 to establish multiple wireless connections for a wireless link. For example, if the user device 102 is operating with a single wireless connection of a 5G NR RAT, the user device 102 may establish a second wireless connection of an LTE RAT. The user device 102 may then interleave transmissions of the first wireless connection and the second wireless connection as discussed herein.

The user device 102 may provide a notification 712 via the user interface 700 to indicate that the user device 102 is entering the multi-carrier mode. The notification 714 is illustrated in this example as a pop-up notification in the display 702, however, other forms of notification 714 may be implemented in addition or in alternative to the pop-up notification. For example, the user device 102 may provide an audible notification, a visible notification via a light emitting diode (LED) indicator that is separate from the display 702, or a motion-based notification such as a vibration of the user device 102.

Techniques for Interleaving RATs

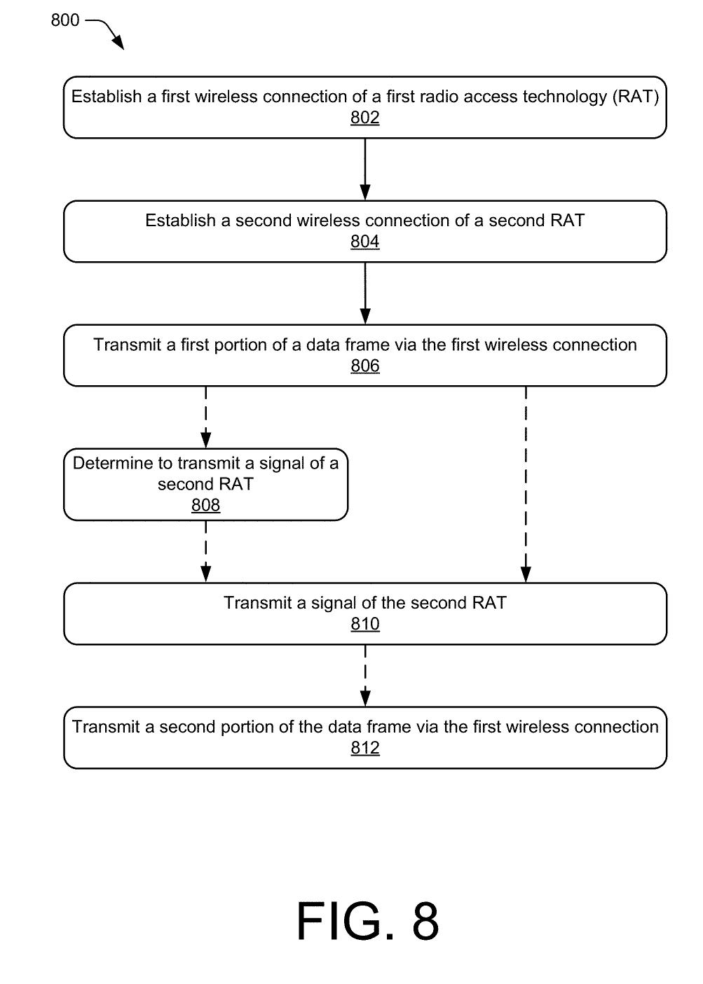

FIGS. 8-11 depict methods for implementing interleaving radio access technologies. These methods are shown as sets of blocks that specify operations performed but are not necessarily limited to the order or combinations shown for performing the operations by the respective blocks. For example, operations of different methods may be combined, in any order, to implement alternate methods without departing from the concepts described herein. In portions of the following discussion, the techniques may be described in reference to FIGS. 1-7, reference to which is made for example only. The techniques are not limited to performance by one entity or multiple entities operating on one device, or those described in these figures.

FIG. 8 illustrates an example method 800 for interleaving radio access technologies, including operations performed by an uplink arbiter, such as the uplink arbiter 116, an a communication module, such as the communication module 120 of the user device 102. In some aspects, operations of the method 800 may be implemented to allow transmissions using a single amplifier and transmission chain via a wireless link including two or more wireless connections using different RATs. The example method 800 may be implemented using a single transmission chain or power amplifier to transmit the data frame via a first wireless connection and a second wireless connection.

At operation 802, a user device establishes, via a transceiver of the user device, a first wireless connection of a first RAT. At operation 804, the user device established a second wireless connection of a second RAT. For example, the user device 102 establishes the first wireless connection 210 and the second wireless connection 212 for communicating with the base station 104. The user device 102 may determine that it would be beneficial to transmit a signal of the second wireless connection during a particular, or recurring, data frame. The determination may be based on the signal having a priority that is higher than a priority of data that would otherwise be scheduled for transmitting during the data frame via the first wireless connection. Additionally or alternatively, the determination may be based on a scheduled reception of the second wireless connection being scheduled before a regularly-scheduled transmission of the second wireless connection. Therefore, it may be beneficial to transmit a signal such that the scheduled reception of the second wireless connection is scheduled between a transmission of the signal and the regularly-scheduled transmission of the second wireless connection.

At operation 806, the user device receives a coordinated uplink schedule. The user device may receive the coordinated uplink schedule, in whole, from one of the first wireless connection or the second wireless connection. Alternatively, the user device receives the coordinated uplink schedule in part via the first wireless connection and in part via the second wireless connection. For example, the base station 104 provides the coordinated uplink schedule to the user device 102. Further, the base station 104 may coordinate with another base station, such as a base station providing the second wireless connection, to generate the coordinated uplink schedule. The coordinated uplink schedule provides a schedule to the user device 102 for transmitting a first portion of a data frame via the first wireless connection of the first RAT and a second portion of the data frame via the second wireless connection of the second RAT. The coordinated uplink schedule may avoid, or reduce a likelihood of causing, transmissions by the user device 102 over the first wireless connection and the second wireless connection at a same time.

At operation 808, the user device transmits, via a transmitter, a first portion of a data frame via the first wireless connection of the first RAT. For example, the user device 102 transmits data during one of the subframe 308, the first portion 422, the subframe 526, or the slot 550. This data may be, for instance, application data such as updates for background applications of the user device 102 or video content.

At operation 810, the user device transmits, via the transmitter and after the first portion of the data frame, a signal via the second wireless connection of the second RAT. For example, the user device 102 transmits data via the subframe 318, the portion 424, the subframe 510, or the slot 548.

At optional operation 812, the user device transmits, via the transmitter, a second portion of the data frame via the first wireless connection. For example, the user device 102 may transmit data the portion 426, the subframe 532, or the subframe 542.

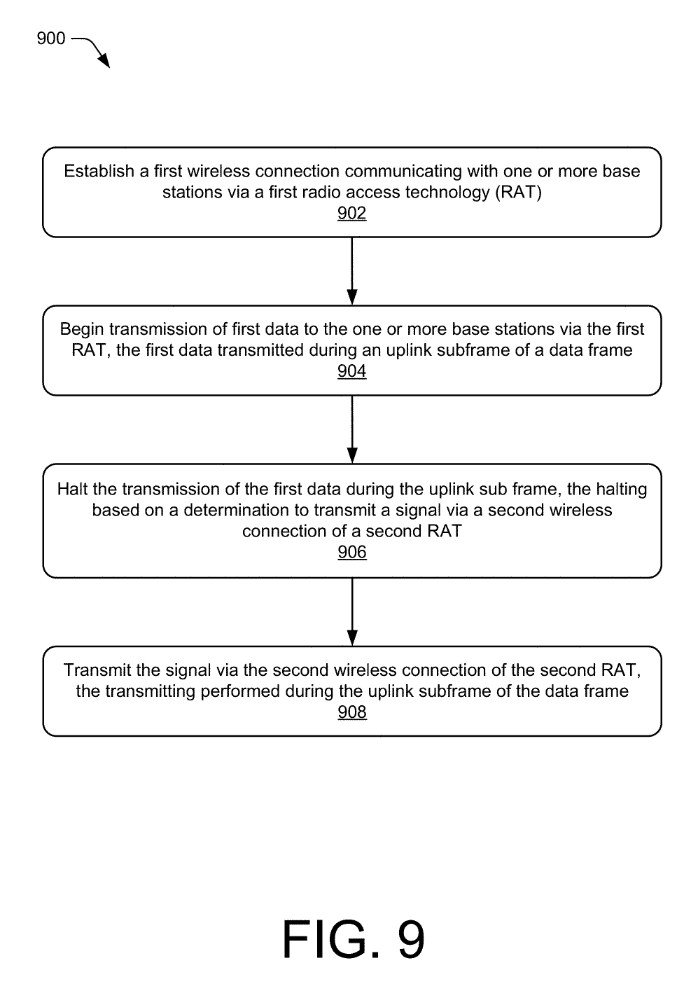

FIG. 9 illustrates an example method 900 for interleaving radio access technologies, including operations performed by an uplink arbiter, such as the uplink arbiter 116, an a communication module, such as the communication module 120 of the user device 102. In some aspects, operations of the method 900 may be implemented to allow the user device 102 to transmit over a first wireless connection of a first RAT and a second wireless connection of a second RAT using a single amplifier or transmission chain of a hardware-based transceiver.

At operation 902, a user device establishes, via a transceiver of the user device, a first wireless connection with one or more base stations via a first RAT. For example, the user device 102 establishes the first wireless connection 210 for communicating with the base station 104.

At operation 904, the user device begins transmission, via the transceiver of the user device, of first data to the one or more base stations. The first data begins transmission via the first wireless connection of the first RAT and is transmitted during an uplink subframe of the data frame. For example, the first portion 422 of the subframe 406 is transmitted as part of beginning the transmission of a combined first data including the first portion 422 and the third portion 426.

At operation 906, the user device halts the transmission of the first data during the uplink subframe. The halting is based on a determination to transmit a signal via a second wireless connection of a second RAT. For example, the uplink arbiter determines to halt the transmission of the combined first data including the first portion 422 and the third portion 426.

At operation 908, the user device transmits, via the transceiver of the user device, the signal via the second wireless connection of the second RAT. The transmitting is performed during the uplink subframe. For example, the user device 102 transmits, via a transmitter of the communication module 120, the second portion 424 of the subframe 406 over the second RAT uplink 218.

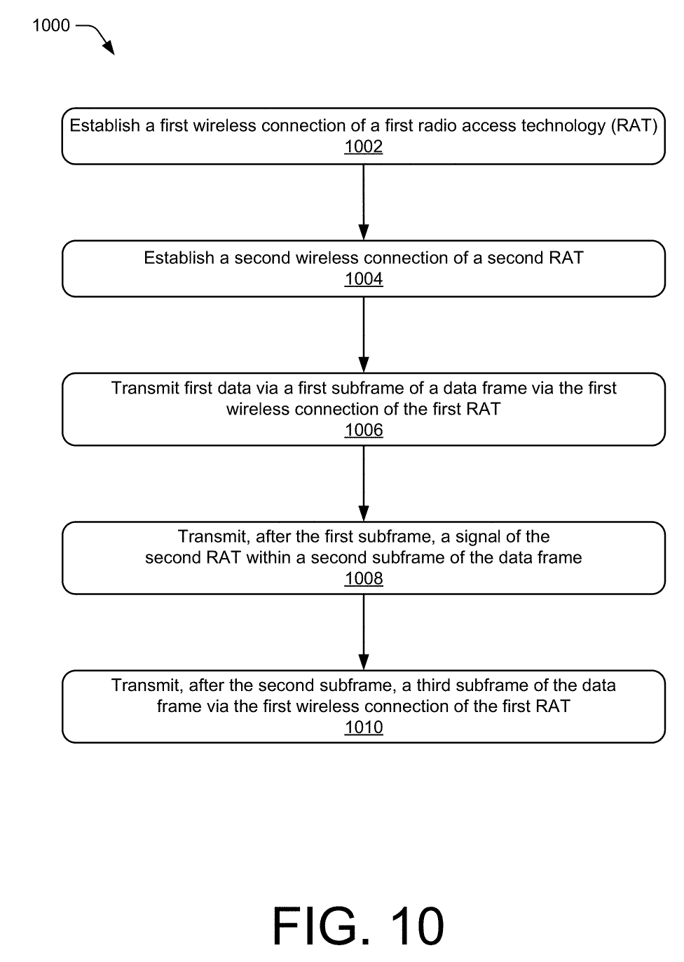

FIG. 10 illustrates an example method 1000 for interleaving radio access technologies, including operations performed by an uplink arbiter, such as the uplink arbiter 116, an a communication module, such as the communication module 120 of the user device 102. In some aspects, operations of the method 1000 may be implemented to allow the user device to transmit using a single amplifier or transmission chain via a wireless link including two or more wireless connections using different RATs.

At operation 1002, a user device establishes, via a transceiver of the user device, a first wireless connection of a first RAT. At operation 1004, the user device established a second wireless connection of a second RAT. For example, the user device 102 establishes the first wireless connection 210 and the second wireless connection 212 for communicating with the base station 104.

At operation 1006, the user device receives a coordinated uplink schedule. The user device may receive the coordinated uplink schedule, in whole, from one of the first wireless connection or the second wireless connection. Alternatively, the user device receives the coordinated uplink schedule in part via the first wireless connection and in part via the second wireless connection. For example, the base station 104 provides the coordinated uplink schedule to the user device 102. Further, the base station 104 may coordinate with another base station, such as a base station providing the second wireless connection, to generate the coordinated uplink schedule. The coordinated uplink schedule provides a schedule to the user device 102 for transmitting a first portion of a data frame via the first wireless connection of the first RAT and a second portion of the data frame via the second wireless connection of the second RAT. The coordinated uplink schedule may avoid, or reduce a likelihood of causing, transmissions by the user device 102 over the first wireless connection and the second wireless connection at a same time.

At operation 1008, the user device transmits, via a transmitter of the transceiver of the user device and according to the coordinated uplink schedule, first data via a first subframe of a date frame via the first wireless connection. For example, the user device 102 transmits first data via the subframe 526. At operation 1010, the user device transmits, via the transmitter and after transmitting the first data and according to the coordinated uplink schedule, a signal of the second RAT within a second subframe of the data frame. For example, the user device 102 transmits the signal during the subframe 510.

At operation 1010 the user device transmits, via the transmitter and after the second subframe, second data via a third subframe of the data frame via the first wireless connection of the first RAT. The user device transmits the second data according to the coordinated uplink schedule. For example, the user device 102 may resume transmitting via the first wireless connection 210 via the subframe 532.

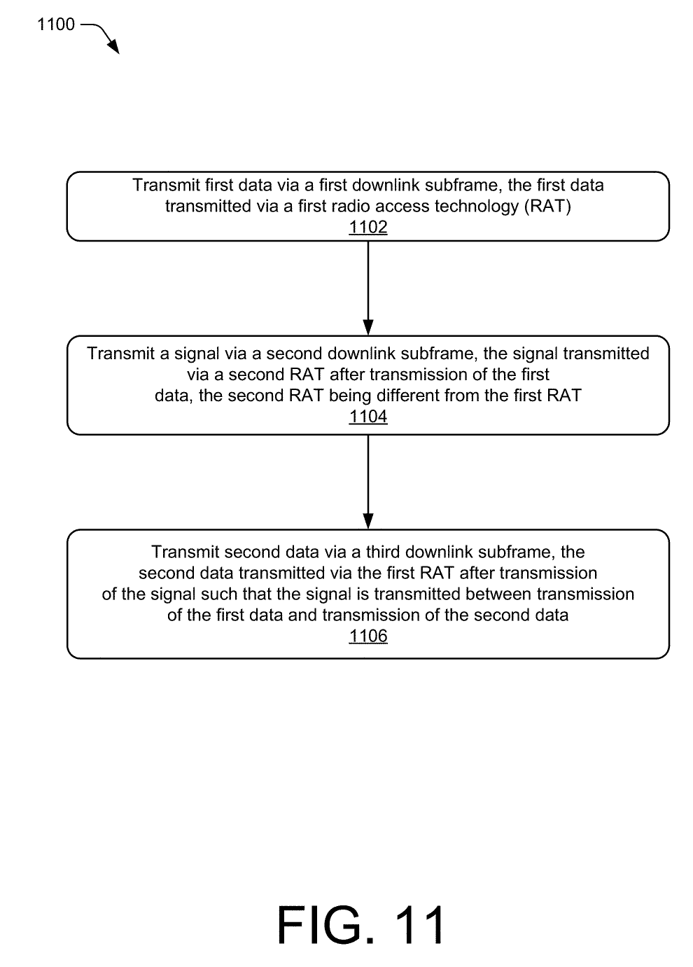

FIG. 11 illustrates an example method 1100 for interleaving radio access technologies, including operations performed by scheduling agent, such as the scheduling agent 126 of the base station 104 or an MME, such as the MME 208. In some aspects, operations of the method 1100 may be implemented to allow transmissions or receipts using a single amplifier and transmission chain via a wireless link including two or more wireless connections using different RATs.

At optional operation 1102, a base station providing a first wireless connection of a first RAT to a user device coordinates an uplink schedule with a provider of another wireless connection. For example, the base station 104 may coordinate with a second base station providing a second wireless connection of a second RAT to generate a coordinated uplink schedule or a coordinated downlink schedule.

At operation 1104, the base station transmits a coordinated uplink schedule to the user device. For example, the base station 104 transmits the coordinated uplink schedule to the user device 102. The coordinated uplink schedule may avoid, or reduce a likelihood of causing, one or both of transmissions or receptions via the first wireless connection and the second wireless connection at a same time.

At operation 1106, a base station transmits first data via a first downlink subframe. The first data is transmitted via a first RAT. For example, the base station 104 transmits first data to the user device 102 via the subframe 506 over the first RAT downlink 216.

At operation 1108, the base station transmits second data via a second downlink subframe. The second data is transmitted via a second RAT after transmission of the first data. For example, the first data is transmitted via the second RAT downlink 220.

At operation 1110, the base station transmits third data via a third downlink subframe of the first RAT. The third downlink subframe is scheduled after the second downlink subframe such that the second data is transmitted between transmission of the first data and transmission of the third data.

In an example implementation of the method 1100, the base station 104 transmits first data via the first wireless connection 210 during the downlink subframe 506. The base station 104 then transmits an SRS during the downlink subframe 530 via the second wireless connection 212. After transmitting via the downlink subframes 506 and 530, the base station 104 transmits second data during the downlink subframe 512 via the first wireless connection 210. This transmitting schedule results in the base station transmitting via only one wireless connection at a time. This allows the user device 102 to operate with a single receiver when communicating with both wireless connections during a data frame.

In another example implementation of the method 1100, the base station 104 transmits first data via the first wireless connection 210 during the downlink subframe 506. Another base station 104 then transmits an SRS during the downlink subframe 530 via the second wireless connection 212. After transmissions via the downlink subframes 506 and 530, the base station 104 transmits second data during the downlink subframe 512 via the first wireless connection 210. This transmitting schedule results in the base stations collectively transmitting via only one wireless connection at a time. This allows the user device 102 to operate with a single receiver when communicating with both wireless connections during a data frame.

Although techniques using and apparatuses for interleaving radio access technologies have been described in language specific to features and/or methods, it is to be understood that the subject of the appended claims is not necessarily limited to the specific features or methods described. Rather, the specific features and methods are disclosed as example ways in which interleaving radio access technologies can be implemented.

What is claimed is:

1. A method performed by a user device, the method comprising:
establishing a first wireless connection of a first radio access technology (RAT);
establishing a second wireless connection of a second RAT;
receiving, via one or both of the first wireless connection or the second wireless connection, a coordinated uplink schedule for transmitting a first portion of a data frame via the first wireless connection of the first RAT and a second portion of the data frame via the second wireless connection of the second RAT;
transmitting, via a transmitter, the first portion of the data frame via the first wireless connection of the first RAT, the first portion of the data frame transmitted according to the coordinated uplink schedule;
transmitting, via the transmitter and after the first portion of the data frame, a signal via the second wireless connection of the second RAT, the signal transmitted according to the coordinated uplink schedule; and
transmitting, via the transmitter and after the signal, the second portion of the data frame via the first wireless connection of the first RAT, the second portion of the data frame transmitted according to the coordinated uplink schedule.

2. The method as recited in claim 1, wherein the first RAT is a Long Term Evolution (LTE) RAT and the second RAT is a 5^{th} generation (5G) new radio (NR) RAT.

3. The method as recited in claim 1, wherein the first RAT is a 5^{th} generation (5G) new radio (NR) RAT and the second RAT is a Long Term Evolution (LTE) RAT.

4. The method as recited in claim 1, further comprising determining, by an arbiter of the user device, that it would be beneficial to transmit the signal via the second wireless connection of the second RAT during the data frame based on the signal having a priority that is higher than a priority of data that would otherwise be scheduled for transmitting during the data frame via the first wireless connection.

5. The method as recited in claim 1, wherein the first wireless connection and the second wireless connection use co-banded frequency ranges.

6. The method as recited in claim 1, wherein the signal includes a sounding reference signal to improve a signal quality for the second wireless connection.

7. The method as recited in claim 1, wherein the user device uses a single transmission chain to transmit the data frame via the first wireless connection and the second wireless connection.

8. The method as recited in claim 1, wherein
the second wireless connection includes a regularly-scheduled transmission and a scheduled reception; and
the scheduled reception of the second wireless connection is scheduled between the transmission of the signal via the second wireless connection and the regularly-scheduled transmission of the second wireless connection.

9. A user device comprising:
a processor;
a hardware based transceiver including a transmission chain; and
a computer-readable storage medium having stored thereon instructions that, responsive to execution by the processor, cause the processor to perform operations comprising:
establishing, via the hardware-based transceiver, a first wireless connection with one or more base stations via a first radio access technology (RAT);
beginning transmission, via the transmission chain of the hardware-based transceiver, of data to the one or more base stations via the first wireless connection of the first RAT, the data transmitted during an uplink subframe of a data frame;
halting the transmission of the data during the uplink subframe, the halting based on a determination to transmit a signal via a second wireless connection of a second RAT; and
transmitting, via the transmission chain of the hardware-based transceiver, the signal via the second wireless connection of the second RAT, the transmitting performed during the uplink subframe.

10. The user device as recited in claim 9, wherein the determination to transmit the signal via the second RAT is based at least in part on a priority of the signal being higher than a priority of the data.

11. The user device as recited in claim 9, wherein the operations further comprise resuming the transmission, for a remaining transmission time of the uplink subframe, of the data to the one or more base stations via the first RAT.

12. The user device as recited in claim 9, wherein the signal includes a sounding reference signal to improve a signal quality for the second wireless connection.

13. The user device as recited in claim 9, wherein the signal includes a random access channel (RACH) communication, an access probe, or a channel request.

14. The user device as recited in claim 9, wherein the signal includes a radio resource control (RRC) communication.

15. The user device as recited in claim 9, wherein the signal includes a non-access stratum communication.

16. A method performed by a user device, the method comprising:
establishing a first wireless connection of a first radio access technology (RAT);
establishing a second wireless connection of a second RAT;
receiving, via one or both of the first wireless connection or the second wireless connection, a coordinated uplink schedule for transmitting a first portion of a data frame via the first wireless connection of the first RAT and a second portion of the data frame via the second wireless connection of the second RAT;
transmitting, via a transmitter, first data within a first subframe of the first portion of the data frame via the first wireless connection of the first RAT, the first data transmitted according to the coordinated uplink schedule;
transmitting, via the transmitter and after the first subframe, a signal via the second wireless connection of the second RAT within a second subframe of the second portion of the data frame, the signal transmitted according to the coordinated uplink schedule; and
transmitting, via the transmitter and after the second subframe, second data via a third subframe of the data frame via the first wireless connection of the first RAT, the second data transmitted according to the coordinated uplink schedule.

17. The method as recited in claim 16, wherein the first RAT is a 4th generation long term evolution (4G LTE) RAT and the second RAT is a 5^{th} generation new radio (5G NR) RAT.

18. The method as recited in claim 16, wherein the first RAT is a 5th generation new radio (5G NR) RAT and the second RAT is a 4^{th} generation long term evolution (4G LTE) RAT.

19. The method as recited in claim 16, wherein the signal includes one or more of:
a sounding reference signal;
a random access channel (RACH) communication;
a radio resource control (RRC) communication; or
a non-access stratum communication.

20. The method as recited in claim 16, wherein the transmitter includes a single transmission chain.
